(19) United States
(12) Patent Application Publication
(10) Pub. No.: US 2026/0082995 A1
(43) Pub. Date: Mar. 19, 2026

(54) POWER MODULE

(71) Applicant: Advanced Semiconductor Engineering, Inc., Kaohsiung (TW)

(72) Inventors: Yuhsien CHIEN, Kaohsiung (TW); Peinung WU, Kaohsiung (TW); Chingyao HSU, Kaohsiung (TW); Jenchun CHEN, Kaohsiung (TW)

(73) Assignee: Advanced Semiconductor Engineering, Inc., Kaohsiung (TW)

(21) Appl. No.: 18/885,462

(22) Filed: Sep. 13, 2024

(51) Int. Cl. H01L 25/065; H01L 23/00; H01L 23/31; H01L 23/538

(52) U.S. Cl. CPC H10W 90/00; H10W 70/611; H10W 74/111; H10W 90/401; H10W 72/07354; H10W 72/347; H10W 90/734

(57) ABSTRACT

The present disclosure relates to a power module. The power module includes a first substrate having a first surface and a second surface opposite to the first surface; a first die disposed on the first surface of the first substrate; and a second die disposed on the second surface of the first substrate, wherein at least one of the first die and the second die is a power die. A first thickness of the first die is different from a second thickness of the second die.

### BACKGROUND

### 1. Technical Field

The present disclosure relates generally to a power module, and more particularly to a power module including elastic structures stacked on power dies.

### 2. Description of the Related Art

As power modules are required to supply higher power to fulfill increased charge rates, heat dissipation becomes more challenging. Currently, power modules may have a double-sided cooling arrangement including wiring array between the sides. Space required for the wiring may necessitate additional spacers, complicating efforts to conserve total height of the module. An improved power module is thus needed.

### SUMMARY

In some embodiments, a power module includes a first substrate having a first surface and a second surface opposite to the first surface; a first die disposed on the first surface of the first substrate; and a second die disposed on the second surface of the first substrate, wherein at least one of the first die and the second die is a power die. A first thickness of the first die is different from a second thickness of the second die.

In some embodiments, a power module includes a first substrate having a first surface and a second surface opposite to the first surface; a first power die disposed on the first surface of the first substrate; and a second power die disposed on the second surface of the first substrate, wherein a first area of the first power die is different from a second area of the second power die from a top view.

In some embodiments, a power module includes a first substrate having a first surface and a second surface opposite to the first surface; a first die disposed on the first surface of the first substrate; and a second die disposed on the second surface of the first substrate, wherein at least one of the first die and the second die is a power die, and wherein the first die and the second die are misaligned in a cross sectional view.

### BRIEF DESCRIPTION OF THE DRAWINGS

Aspects of the present disclosure are readily understood from the following detailed description when read with the accompanying figures. It should be noted that various features may not be drawn to scale. The dimensions of the various features may be arbitrarily increased or reduced for clarity of discussion.

FIG. 1 is a cross-section of a power module, in accordance with some embodiments of the present disclosure.

FIG. 2A is a bottom view of a substrate of a power module, in accordance with some embodiments of the present disclosure.

FIG. 2B is a top view of a substrate of a power module, in accordance with some embodiments of the present disclosure.

FIG. 3A is a bottom view of a substrate of a power module, in accordance with some embodiments of the present disclosure.

FIG. 3B is a top view of a substrate of a power module, in accordance with some embodiments of the present disclosure.

FIG. 4A is a top view of a substrate of a power module, in accordance with some embodiments of the present disclosure.

FIG. 4B is a bottom view of a substrate of a power module, in accordance with some embodiments of the present disclosure.

FIG. 5 is a cross-section of a power module, in accordance with some embodiments of the present disclosure.

FIG. 6A is a bottom view of a substrate of a power module, in accordance with some embodiments of the present disclosure.

FIG. 6B is a top view of a substrate of a power module, in accordance with some embodiments of the present disclosure.

FIG. 7A is a bottom view of a substrate of a power module, in accordance with some embodiments of the present disclosure.

FIG. 7B is a top view of a substrate of a power module, in accordance with some embodiments of the present disclosure.

FIG. 8A is a top view of a substrate of a power module, in accordance with some embodiments of the present disclosure.

FIG. 8B is a bottom view of a substrate of a power module, in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

The following disclosure provides different embodiments, or examples, for implementing different features of the provided subject matter. Specific examples of components and embodiments are recited herein. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may be formed between the first and second features, such that the first and second features may not be in direct contact. The present disclosure may repeat reference numerals and/or letters in the various examples. This repetition is for simplicity and clarity and does not in itself dictate a relationship between the various embodiments and/or configurations discussed.

Embodiments of the present disclosure are discussed in detail as follows. It should be appreciated, however, that the present disclosure provides many applicable concepts that can be embodied in a wide variety of specific contexts. The specific embodiments discussed are merely illustrative and do not limit the scope of the disclosure.

The total size of power modules can be reduced by an additional heat dissipation substrate between power dies. The power module can include three substrates for heat dissipation, and different dies can be arranged between each two substrates based on die type. The same types of die, which have the same thickness, can be arranged in the same elevation. Therefore, after molding, the power module can present a decreased height. The additional substrate may further provide electric conductivity, thermal conductivity, and support.

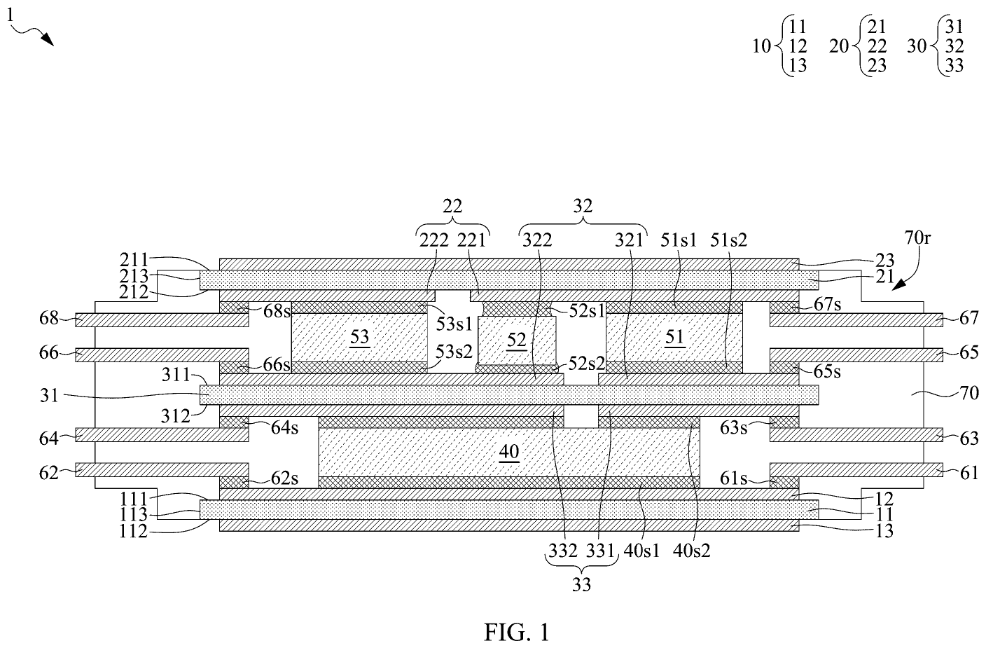

FIG. 1 is a cross-section of a power module 1, in accordance with some embodiments of the present disclosure. The power module 1 may include substrates 10, 20, and 30, dies 40, 51, 52, and 53, leadframes 61, 62, 63, 64, 65, 66, 67, and 68, and an encapsulant 70.

Referring to FIG. 1, the substrate 10 may include a core layer 11 and two conductive layers 12 and 13. The core layer 11 may have a first surface 111 and a second surface 112 opposite to the first surface 111. The conductive layer 12 may be disposed on the first surface 111 of the core layer 11. The conductive layer 12 may be patterned. The patterned conductive layer 12 may be configured to provide electrical connection. In some embodiments, the conductive layer 13 may be disposed on the second surface 112 of the core layer 11. The conductive layer 13 may be free from being patterned. That is, the conductive layer 13 may be a conductive plate without any patterning. For example, the conductive layer 13 may be a square plate. In other embodiments, the conductive layer 13 may be any suitable shape.

In some embodiments, the core layer 11 may be disposed between conductive layers 12 and 13. The width of the core layer 11 may equal or exceed that of conductive layers 12 and 13. In some embodiments, the width of the conductive layer 12 may be substantially identical to that of the conductive layer 13.

In some embodiments, the core layer 11 may be a dielectric layer. For example, the core layer 11 may include a ceramic material. In some embodiments, the conductive layers 12 and 13 may include a conductive material such as a metal or metal alloy. Examples of the conductive material include aluminum (Al), copper (Cu), or an alloy thereof. In some embodiments, the substrate 10 may be a direct bonded copper (DBC) substrate or an active metal brazed (AMB) substrate. In some embodiments, the substrate 10 can provide electrical conductivity with thermal dissipation.

In some embodiments, the substrate 20 may be disposed on the substrate 10. The substrate 20 may include a core layer 21 and two conductive layers 22 and 23. The core layer 21 may have a first surface 211 and a second surface 212 opposite to the first surface 211. The conductive layer 22 may be disposed on the second surface 212 of the core layer 21. The conductive layer 22 may be patterned. The patterned conductive layer 22 may be configured to provide electrical connection. In some embodiments, the conductive layer 23 may be disposed on the first surface 211 of the core layer 21. The conductive layer 23 may be free from being patterned. That is, the conductive layer 23 may be a conductive plate without any patterning. For example, the conductive layer 23 may be a square plate. In other embodiments, the conductive layer 23 may be any suitable shape.

In some embodiments, the core layer 21 may be disposed between the conductive layers 22 and 23. The width of the core layer 21 may equal or exceed that of the conductive layers 22 and 23. In some embodiments, width of the conductive layer 22 may be identical to that of the conductive layer 23.

In some embodiments, the core layer 21 may be a dielectric layer. For example, the core layer 21 may include a ceramic material. In some embodiments, the conductive layers 22 and 23 may include a conductive material such as a metal or metal alloy. Examples of the conductive material include aluminum (Al), copper (Cu), or an alloy thereof. In some embodiments, the substrate 20 may be a direct bonded copper (DBC) substrate or an active metal brazed (AMB) substrate. In some embodiments, the substrate 20 can provide electrical conductivity with thermal dissipation.

In some embodiments, the substrate 30 may be disposed on the substrate 10. The substrate 30 may be disposed between the substrates 10 and 20. The substrate 30 may be spaced apart from the substrates 10 and 20 by a uniform distance. In some embodiments, the vertical distance between the substrate 10 and 30 may be different from the vertical distance between the substrate 20 and 30. The substrate 30 may include a core layer 31 and two conductive layers 32 and 33. The core layer 31 may have a first surface 311 and a second surface 312 opposite to the first surface 311. The conductive layer 32 may be disposed on the first surface 311 of the core layer 31. The conductive layer 32 may be patterned. The patterned conductive layer 32 may be configured to provide electrical connection. In some embodiments, the conductive layer 33 may be disposed on the second surface 312 of the core layer 31. Conductive layer 33 may also be patterned.

In some embodiments, the core layer 31 may be disposed between the conductive layers 32 and 33. The width of the core layer 31 may equal or exceed that of the conductive layers 32 and 33. In some embodiments, width of the conductive layer 32 may be identical to that of the conductive layer 33. In some embodiments, conductive layers 32 and 33 can be separated by the core layer 31.

In some embodiments, the core layer 31 may be a dielectric layer. For example, the core layer 31 may include a ceramic material. In some embodiments, the conductive layers 32 and 33 may include a conductive material such as a metal or metal alloy. Examples of the conductive material include aluminum (Al), copper (Cu), or an alloy thereof. In some embodiments, the substrate 30 may be a direct bonded copper (DBC) substrate or an active metal brazed (AMB) substrate. In some embodiments, the substrate 30 can provide electrical conductivity with thermal dissipation.

In some embodiments, the die 40 may be disposed between the substrates 10 and 20. The die 40 may be disposed between the substrates 10 and 30. The die 40 may be disposed between the conductive layers 12 and 33. In some embodiments, the die 40 may be electrically connected to the conductive layer 12 of the substrate 10. The die 40 may adhere and connect to the substrate 10 through a soldering material 40s1. In some embodiments, the die 40 may be electrically connected to the conductive layer 33 of the substrate 30. The die 40 may adhere and connect to the substrate 30 through a soldering material 40s2. In some embodiments, the soldering materials 40s1 and 40s2 may be solder paste, solder bumps, or solder ball, or non-solder conductive structures such as copper pillar, or a combination thereof. In some embodiments, heat generated by the die 40 may be dissipated by the substrates 10 and 30. In some embodiments, a heatsink (not shown) may be disposed under the conductive layer 13 for dissipating heat from the die 40. That is, the substrate 10 may be configured to establish a thermal dissipation path for the die 40.

In some embodiments, the die 40 may be an electronic component such as a power die. The die 40 may be a transistor or a diode, for example an insulated gate bipolar transistor (IGBT). In some embodiments, the die 40 may be a three-terminal element. In some embodiments, the die 40 may have a first terminal connected to a portion 331 of the conductive layer 33, a second terminal connected to a portion 332 of the conductive layer 33, and a third terminal connected to the conductive layer 12. In some embodiments, the first terminal, the second terminal, and the third terminal of the die 40 may be a gate, an emitter, and a collector of the IGBT, respectively.

In some embodiments, dies 51, 52, and 53 may be disposed between the substrates 10 and 20. The dies 51, 52, and 53 may be disposed between the substrates 20 and 30. The dies 51, 52, and 53 may be disposed between the conductive layers 22 and 32. In some embodiments, the dies 51, 52, and 53 may be electrically connected to the conductive layer 22 of the substrate 20. The dies 51, 52, and 53 may be electrically connected to the conductive layer 32 of the substrate 30.

The die 51 may adhere and connect to the substrate 20 through a soldering material 51s1, and to the substrate 30 through a soldering material 51s2. The die 52 may adhere and connect to the substrate 20 through a soldering material 52s1, and to the substrate 30 through a soldering material 52s2. The die 53 may adhere and connect to the substrate 20 through a soldering material 53s1, and to the substrate 30 through a soldering material 53s2.

In some embodiments, a thickness of the soldering material 52s2 may be different from a thickness of the soldering material 51s2. For example, the thickness of the soldering material 52s2 may be less than the thickness of the soldering material 51s2. In some embodiments, the thickness difference between the soldering materials 52s2 and 51s2 may be regarded as an acceptable tolerance. In some embodiments, a thickness of the soldering material 53s2 may be identical to a thickness of the soldering material 51s2. In some embodiments, a thickness of the soldering material 52s1 may be different from a thickness of the soldering material 51s1. For example, the thickness of the soldering material 52s1 may be greater than the thickness of the soldering material 51s1. In some embodiments, the thickness difference between the soldering materials 52s1 and 51s1 may be regarded as an acceptable tolerance. In some embodiments, a thickness of the soldering material 53s1 may be identical to a thickness of the soldering material 51s1.

The soldering material 52s2 may have a curved lateral surface. For example, the lateral surface of the soldering material 52s2 may be convex. In some embodiments, the soldering material 52s2 may cover a lateral surface of the die 52. The soldering material 52s1 may have a curved lateral surface. For example, the lateral surface of the soldering material 52s1 may be concave. In some embodiments, the top surface of the die 52 may be exposed by the soldering material 52s1.

In some embodiments, the thicknesses of the soldering materials 51s1, 51s2, 52s1, 52s2, 53s1, and 53s2 may be different from each other. The thickness difference between the soldering materials may be regarded as an acceptable tolerance. Given that the substrate 30 is spaced apart from the substrate 20 by a uniform distance and that the dies 51, 52, and 53 have the same thickness, the different thicknesses of soldering materials 51s1, 51s2, 52s1, 52s2, 53s1, and 53s2 can provide a buffer for the total height of the power module 1.

In some embodiments, the soldering materials 51s1, 51s2, 52s1, 52s2, 53s1, and 53s2 may be solder paste, solder bumps, or solder ball, or non-solder conductive structures such as copper pillar, or a combination thereof. In some embodiments, heat generated by the dies 51, 52, and 53 may be dissipated by the substrates 20 and 30. In some embodiments, a heatsink (not shown) may be disposed above the conductive layer 23 for dissipating heat from the dies 51, 52, and 53. That is, the substrate 20 may be configured to establish a thermal dissipation path for the dies 51, 52, and 53. The number of dies 51, 52, and 53 is not limited.

In some embodiments, dies 51, 52, and 53 may be of the same the type, and may be of identical thickness. In some embodiments, a respective elevation of the dies 51, 52, 53 with regard to the substrate 30 may be identical. For example, a distance between the top surface of the die 51 and the substrate 30 may be identical to that between the top surface of the die 52 and the substrate 30. Similarly, the distance between the top surface of the die 51 and the substrate 30 may be identical to that between the top surface of the die 53 and the substrate 30.

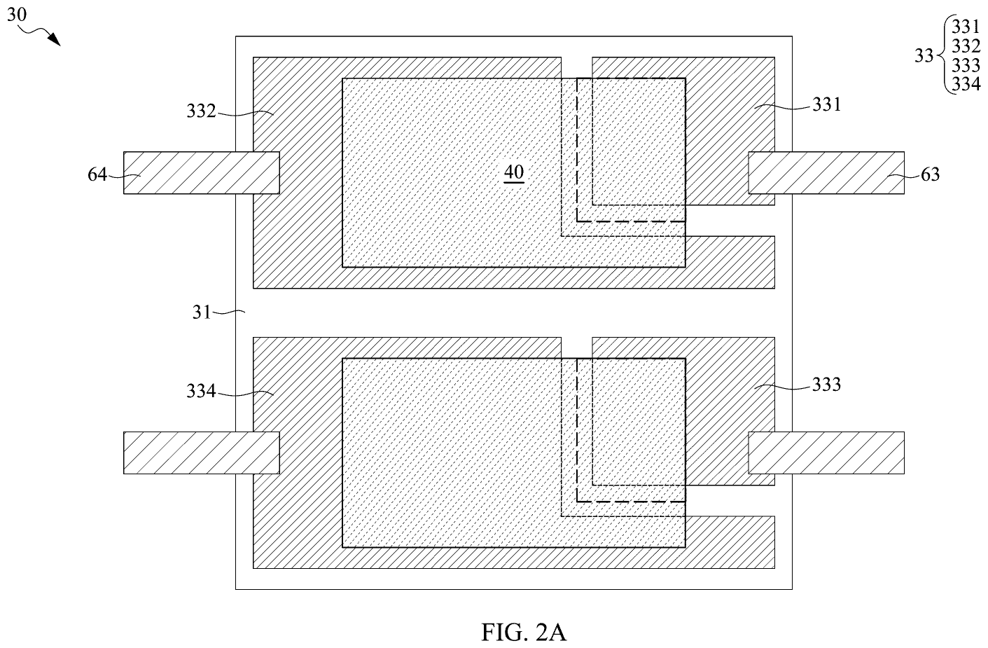

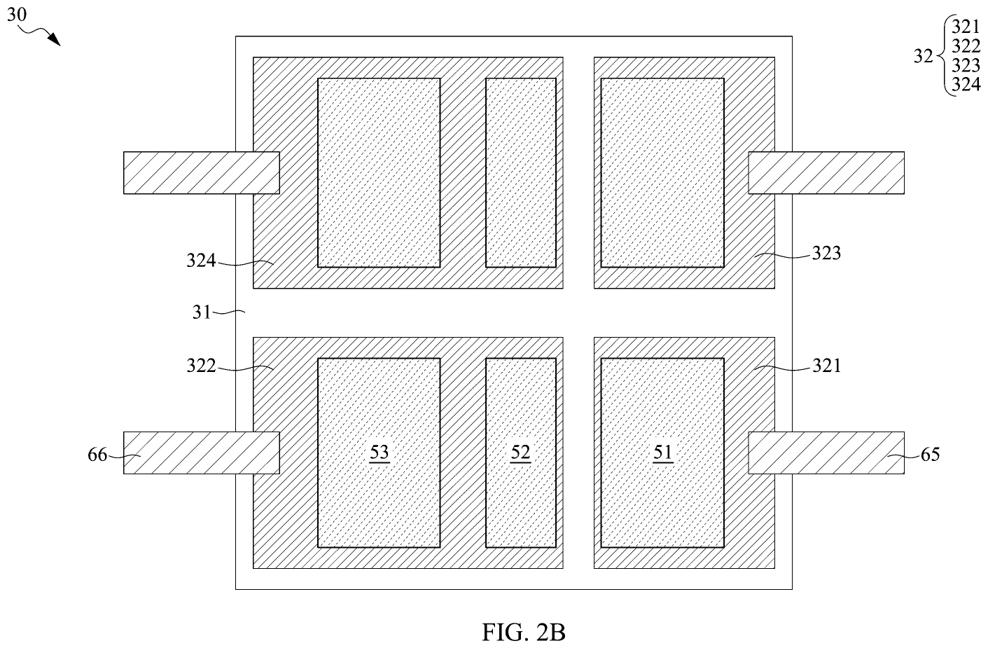

In some embodiments, die 51 may be of different size than the die 52. For example, the die 51 may be wider than the die 52. The width of die 51 may be identical to that of the die 53. In some embodiments, an area of the die 51 may be different from that of the die 52 in a top view (see FIG. 2B).

In some embodiments, the dies 51, 52, and 53 may be power dies. The dies 51, 52, and 53 may be diodes or transistors (for example, an IGBT). In some embodiments, the dies 51, 52, and 53 may be a two-terminal element.

The conductive layer 32 of the substrate 30 may include a first portion 321 and a second portion 322 spaced apart from the first portion 321. The die 51 may be disposed on and connected to the first portion 321 of the conductive layer 32. The dies 52 and 53 may be disposed on and connected to the second portion 322 of the conductive layer 32. In some embodiments, the dies 52 and 53 may be electrically connected through the second portion 322 of the conductive layer 32.

The conductive layer 22 of the substrate 20 may include a first portion 221 and a second portion 222 spaced apart from the first portion 221. The dies 51 and 52 may be attached to and connected to the first portion 221 of the conductive layer 22. In some embodiments, the dies 51 and 52 may be electrically connected through the second portion 221 of the conductive layer 22. The die 53 may be connected to the second portion 222 of the conductive layer 22.

The dies 51, 52, and 53 may at least partially vertically overlap the die 40. In some embodiments, die 40 and die 51 are misaligned. A projection of a lateral surface (i.e., the right lateral surface) of the die 51 on the substrate 30 may be outside of a projection of the die 40 on the substrate 30. In some embodiments, the die 52 may vertically overlap die 40. A projection of die 52 on the substrate 30 may be completely within a projection of die 40 on the substrate 30. In some embodiments, die 40 and die 53 are misaligned. A projection of a lateral surface (i.e., the left lateral surface) of the die 53 on the substrate 30 may be outside of a projection of the die 40 on the substrate 30.

In some embodiments, die 40 may be wider than dies 51, 52, and 53. In other embodiments, die 40 may be of identical width to dies 51, 52, and 53. In some embodiments, die 40 may be of different thickness from dies 51, 52, and 53. For example, the thickness of the die 40 may be less than the thickness of the dies 51, 52, and 53. In other embodiments, die 40 may be of identical thickness to dies 51, 52, and 53.

In some embodiments, die 40 may be a transistor, and dies 51, 52, and 53 may be diodes. In other embodiments, die 40 may be a diode, and dies 51, 52, and 53 transistors.

Leadframes 61 and 62 may be disposed between substrates 10 and 30, and in some embodiments, on the substrate 10. The leadframes 61 and 62 may adhere and connect to the substrate 10 through a soldering material 61s and 62s, respectively. In some embodiments, the soldering material 61s and 62s may be solder paste, solder bumps, or solder ball, or non-solder conductive structures such as copper pillar, or a combination thereof. The leadframes 61 and 62 may be electrically connected to the die 40 through the substrate 10. The leadframes 61 and 62 may connect the die 40 to the external components or other electrical connection.

In some embodiments, the leadframes 63 and 64 may be disposed between the substrates 10 and 30. The leadframes 63 and 64 may adhere and connect to the substrate 30 through a soldering material 63s and 64s, respectively. In some embodiments, the leadframe 63 may be connected to the first portion 331 of the conductive layer 33 of the substrate 30 through the soldering material 63s. The leadframe 64 may be connected to the second portion 332 of the conductive layer 33 of the substrate 30 through the soldering material 64s. In some embodiments, the soldering material 63s and 64s may be solder paste, solder bumps, or solder ball, or non-solder conductive structures such as copper pillar, or a combination thereof. The leadframes 63 and 64 may be electrically connected to the die 40 through the substrate 30. The leadframes 63 and 64 may connect the die 40 to the external components or other electrical connection.

In some embodiments, the leadframes 65 and 66 may be disposed between the substrates 20 and 30. The leadframes 65 and 66 may adhere and connect to the substrate 30 through a soldering material 65s and 66s, respectively. In some embodiments, the leadframe 65 may be connected to the first portion 321 of the conductive layer 32 of the substrate 30 through the soldering material 65s. The leadframe 66 may be connected to the second portion 322 of the conductive layer 32 of the substrate 30 through the soldering material 66s. In some embodiments, the soldering material 65s and 66s may be solder paste, solder bumps, or solder ball, or non-solder conductive structures such as copper pillar, or a combination thereof. The leadframe 65 may be electrically connected to the die 51 through the substrate 30. The leadframe 66 may be electrically connected to the dies 52 and 53 through the substrate 30. The leadframes 65 and 66 may connect the dies 51, 52, and 53 to the external components or other electrical connection.

In some embodiments, the leadframes 67 and 68 may be disposed between the substrates 20 and 30. The leadframes 67 and 68 may adhere and connect to the substrate 20 through a soldering material 67s and 68s, respectively. In some embodiments, the leadframe 67 may be connected to the first portion 221 of the conductive layer 22 of the substrate 20 through the soldering material 67s. The leadframe 68 may be connected to the second portion 222 of the conductive layer 22 of the substrate 20 through the soldering material 68s. In some embodiments, the soldering material 67s and 68s may be solder paste, solder bumps, or solder ball, or non-solder conductive structures such as copper pillar, or a combination thereof. The leadframe 67 may be electrically connected to the dies 51 and 52 through the substrate 20. The leadframe 68 may be electrically connected to the die 53 through the substrate 20. The leadframes 67 and 68 may connect the dies 51, 52, and 53 to the external components or other electrical connection.

The encapsulant 70 may be disposed between the substrate 10 and 20. In some embodiments, the encapsulant 70 may cover or encapsulate the substrate 30, the dies 40, 51, 52, and 53 and the leadframes 61, 62, 63, 64, 65, 66, 67, and 68. A portion of the leadframes 61, 62, 63, 64, 65, 66, 67, and 68 may protrude from the encapsulant 70, such that the leadframes 61, 62, 63, 64, 65, 66, 67, and 68 can connect the power module 1 to the external components. In some embodiments, the encapsulant 70 may be formed by a molding process. During molding, a mold may fix the substrates 10 and 20 to control the total height of the power module 1. The substrate 30 can split different types of dies on opposite sides, and thus the wires and spacers are not needed, such that the total height of the power module 1 can be decreased. In addition, the substrates 10, 20, and 30 can also provide electric conductivity, thermal conductivity, and support.

In some embodiments, the encapsulant 70 may encapsulate the substrates 10 and 20. The conductive layers 13 and 23 may be exposed by the encapsulant 70. The conductive layers 13 and 23 may be free from contacting with the encapsulant 70. In some embodiments, the first surface 211 of the core layer 21 may be exposed by the encapsulant 70. The encapsulant 70 may cover a lateral surface 213 of the core layer 21. In another embodiment, the encapsulant 70 may partially cover the lateral surface 213. The first surface 211 of the core layer 21 may be substantially coplanar with the top surface of the encapsulant 70. In some embodiments, the second surface 112 of the core layer 11 may be exposed by the encapsulant 70. The encapsulant 70 may cover a lateral surface 113 of the core layer 11. In another embodiment, the encapsulant 70 may partially cover the lateral surface 113. The second surface 112 of the core layer 11 may be substantially coplanar with the bottom surface of the encapsulant 70.

The encapsulant 70 may be recessed at the edges. In some embodiments, the encapsulant 70 may have one or more dents 70r at the corners. Referring to FIG. 1, the dents 70r may be located at four corners/edges of the encapsulant 70. In some embodiments, the dents 70r may be recessed from the top surface of the encapsulant 70. The dents 70r may be recessed from the lateral surface of the encapsulant 70. The dents 70r may be apart from the substrates 10 and 20. In other words, the substrates 10 and 20 may not be exposed by the dents 70r. In some embodiments, the dents 70r may be resulted from the mold shape used in the molding process.

In some embodiments, the encapsulant 70 may include an epoxy resin, a molding compound (e.g., an epoxy molding compound or other molding compound), a polyimide, a phenolic compound or material, a material including a silicone dispersed therein, or a combination thereof.

When the die 40 and the dies 51, 52, and 53 have different thicknesses, the total height of the power module 1 can be controlled by separation thereof by the substrate 30. In such a case, electrical connection of the dies 40, 51, 52, and 53 can be provided by the substrate 30 and the leadframes 63 to 66, and total size of the power module 1 can be controlled and further decreased. In addition, the substrates 10, 20, and 30 can also provide electric conductivity, thermal conductivity, and support. The die 40 can have a thermal dissipation path upward through the substrate 30, and another thermal dissipation path downward through the substrate 10. The dies 51, 52, and 53 can have a thermal dissipation path upward through the substrate 20, and another thermal dissipation path downward through the substrate 30. Each of the dies 40, 51, 52, and 53 can have a double-sided cooling arrangement. Therefore, the power module 1 can have a better heat dissipation.

FIG. 2A is a bottom view of a substrate 30 of a power module, in accordance with some embodiments of the present disclosure. FIG. 2A shows an exemplary pattern of the substrate 30 of FIG. 1. For clarity, FIG. 2A omits the encapsulant 70, the substrate 10, and the leadframes 61 and 62.

Referring to FIG. 2A, the substrate 30 includes the core layer 31 and the patterned conductive layer 33. The patterned conductive layer 33 may include one or more portions 331, 332, 333, and 334, and 334. The portions 331, 332, 333, and 334 of the conductive layers 33 may be spaced apart from each other. In some embodiments, the portions 331, 332, 333, and 334 may be round, square, rectangular, or irregular. The shapes of the portions 331, 332, 333, and 334 may be identical or different.

The size of the portions 331, 332, 333, and 334 may be different. The area of the portion 332 may be greater than that of the portion 331. The area of the portion 334 may be greater than that of the portion 333. In some embodiments, the portions 331 and 333 may be rectangular, and the portions 332 and 334 may be L-shape.

In some embodiments, the portions 331, 332, 333, and 334 of the conductive layer 33 may connect to one or more dies (such as the die 40), such that heat generated by the dies is dissipated to the conductive layer 33. The die 40 may be disposed on the portions 331 and 332. In some embodiments, the die 40 may be connected to the portions 331 and 332 through two terminals, respectively. In some embodiments, the die 45 may be an IGBT. For example, the portion 331 may be connected to a first terminal (for example, the gate) of the die 40, and the portion 332 may be connected to a second terminal (for example, the emitter) of the die 40.

In some embodiments, the leadframe 63 may be disposed on and connected to the portion 331 of the conductive layer 33. In some embodiments, the leadframe 64 may be disposed on and connected to the portion 332 of the conductive layer 33. In some embodiments, the leadframes 63 and 64 may include electrical connectors, other conductive structures, or a combination thereof.

In some embodiments, one or more dies may be disposed on and connected to the portions 333 and 334 of the conductive layer 33. The portions 333 and 334 of the conductive layer 33 may be connected to external components through the leadframes.

FIG. 2B is a top view of a substrate 30 of a power module, in accordance with some embodiments of the present disclosure. FIG. 2B shows an exemplary pattern of the substrate 30 of FIG. 1. For clarity, FIG. 2B omits the encapsulant 70, the substrate 20, and the leadframes 67 and 68.

Referring to FIG. 2B, the substrate 30 includes the core layer 31 and the patterned conductive layer 32. The patterned conductive layer 32 may include one or more portions 321, 322, 323, and 324. The portions 321, 322, 323, and 324 of the conductive layers 32 may be spaced apart from each other. In some embodiments, the portions 321, 322, 323, and 324 may be round, square, rectangular, or irregular. The shapes of the portions 321, 322, 323, and 324 may be identical or different.

The size of the portions 321, 322, 323, and 324 may be different. For example, the area of the portion 322 may be greater than that of the portion 321. The area of the portion 324 may be greater than that of the portion 323. In some embodiments, the area of the portion 323 may be identical to that of the portion 321. The area of the portion 324 may be identical to that of the portion 322. In some embodiments, the portions 321, 322, 323, and 324 may be rectangular.

In some embodiments, the portions 321, 322, 323, and 324 of the conductive layer 32 may connect to one or more dies (such as the dies 51, 52, and 53), such that heat generated by the dies is dissipated to the conductive layer 32. The die 51 may be disposed on and connected to the portion 321. The dies 52 and 53 may be disposed on and connected to the portion 322.

Die 51 may be of different size from die 52. For example, an area of the die 51 may be greater than an area of the die 52. In some embodiments, the area of the die 51 may be identical to that of the die 53.

In some embodiments, the leadframe 65 may be disposed on and connected to the portion 321 of the conductive layer 32. In some embodiments, the leadframe 66 may be disposed on and connected to the portion 322 of the conductive layer 32. In some embodiments, the leadframes 65 and 66 may include electrical connectors, other conductive structures, or a combination thereof.

In some embodiments, one or more dies may be disposed on and connected to the portion 323 or 324 of the conductive layer 32. The portions 323 and 324 of the conductive layer 32 may be connected to external components through the leadframes.

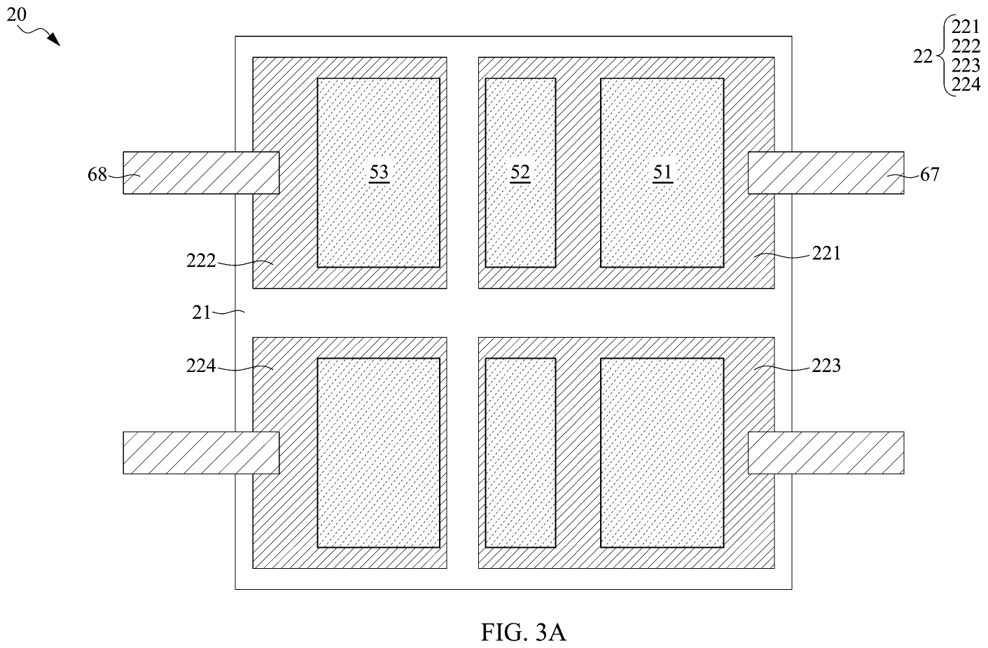

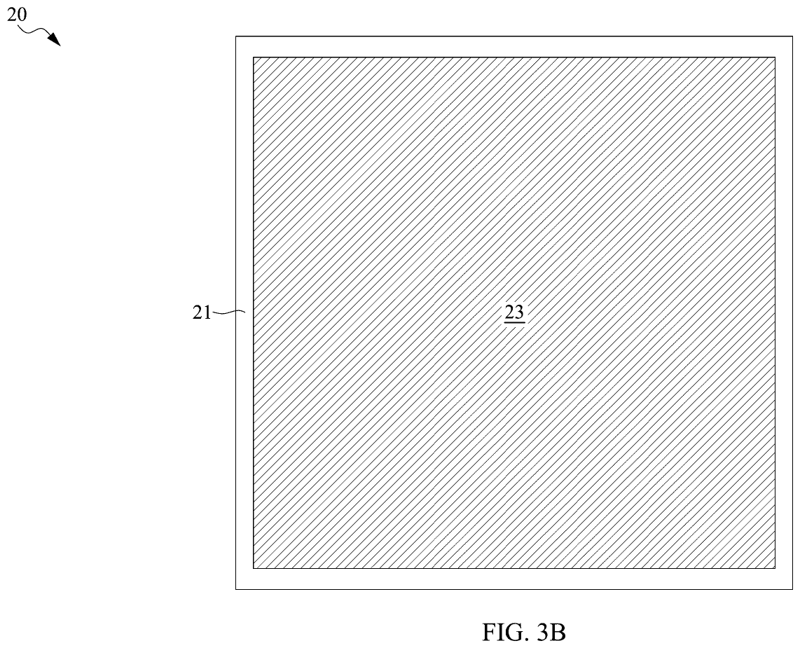

FIG. 3A is a bottom view of a substrate 20 of a power module, in accordance with some embodiments of the present disclosure. FIG. 3A shows an exemplary pattern of the substrate 20 of FIG. 1. For clarity, FIG. 3A omits the encapsulant 70, the substrates 10 and 30, and the leadframes 61 to 66.

Referring to FIG. 3A, the substrate 20 includes the core layer 21 and the patterned conductive layer 22. The patterned conductive layer 22 may include one or more portions 221, 222, 223, and 224. The portions 221, 222, 223, and 224 of the conductive layers 22 may be spaced apart from each other. In some embodiments, the portions 221, 222, 223, and 224 may be round, square, rectangular, or irregular. The shapes of the portions 221, 222, 223, and 224 may be identical or different.

Sizes of portions 221, 222, 223, and 224 may be different. For example, the area of the portion 222 may be less than that of the portion 221. The area of the portion 224 may be less than that of the portion 223. In some embodiments, the area of the portion 223 may be identical to that of the portion 221. The area of the portion 224 may be identical to that of the portion 222. In some embodiments, the portions 221, 222, 223, and 224 may be rectangular.

In some embodiments, the portions 221, 222, 223, and 224 of the conductive layer 22 may connect to one or more dies (such as the dies 51, 52, and 53), such that heat generated by the dies is dissipated to the conductive layer 22. The dies 51 and 52 may be disposed on and connected to the portion 221. The die 53 may be disposed on and connected to the portion 222.

In some embodiments, the leadframe 67 may be disposed on and connected to the portion 221 of the conductive layer 22. In some embodiments, the leadframe 68 may be disposed on and connected to the portion 222 of the conductive layer 22. In some embodiments, the leadframes 67 and 68 may include electrical connectors, other conductive structures, or a combination thereof.

In some embodiments, one or more dies may be disposed on and connected to the portion 223 or 224 of the conductive layer 22. The portions 223 and 224 of the conductive layer 22 may be connected to external components through the leadframes.

FIG. 3B is a top view of a substrate 20 of a power module, in accordance with some embodiments of the present disclosure. FIG. 3B shows an exemplary pattern of the substrate 20 of FIG. 1. For clarity, FIG. 3B omits the encapsulant 70 and the leadframes 61 to 68. Referring to FIG. 3B, the substrate 20 includes the core layer 21 and the conductive layer 23 free from being patterned. In some embodiments, the conductive layer 23 may be round, square, rectangular, or irregular. For example, the conductive layer 23 may be rectangular.

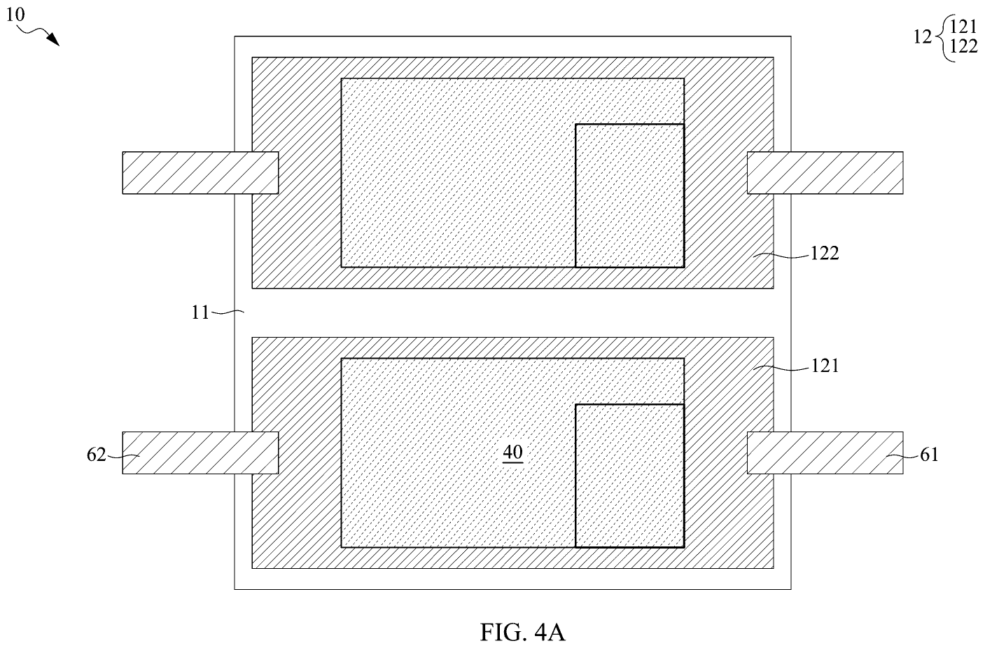

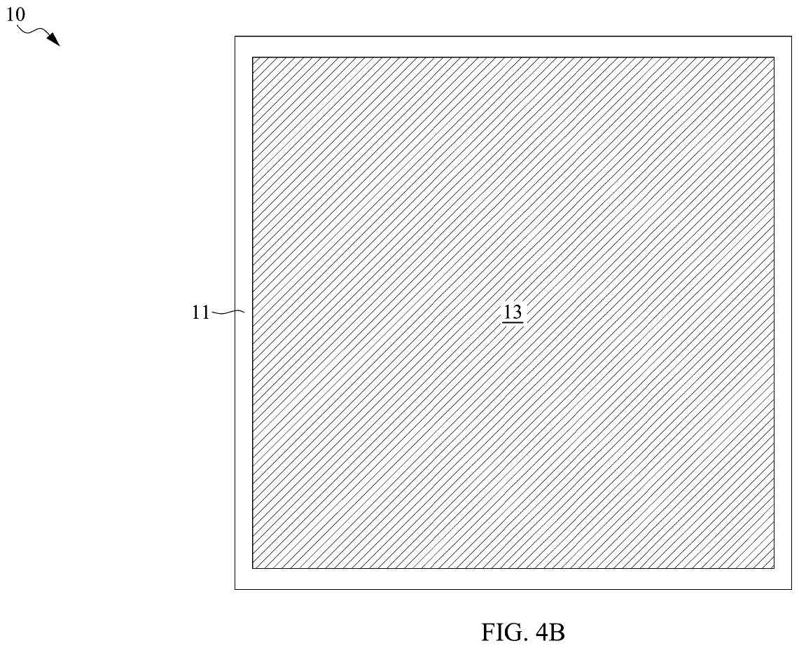

FIG. 4A is a top view of a substrate 10 of a power module, in accordance with some embodiments of the present disclosure. FIG. 4A shows an exemplary pattern of the substrate 10 of FIG. 1. For clarity, FIG. 4A omits the encapsulant 70, the substrates 20 and 30, and the leadframes 63 to 68.

Referring to FIG. 4A, the substrate 10 includes the core layer 11 and the patterned conductive layer 12. The patterned conductive layer 12 may include one or more portions 121 and 122. The portions 121 and 122 of the conductive layers 12 may be spaced apart from each other. The portions 121 and 122 may be round, square, rectangular, or irregular. The shapes of the portions 121 and 122 may be identical or different.

The size of portions 121 and 122 may be the same. For example, the area of the portion 121 may be identical to that of the portion 122. In some embodiments, the portions 121 and 122 may be rectangular.

In some embodiments, the portions 121 and 122 of the conductive layer 12 may connect to one or more dies (such as the die 40), such that heat generated by the dies is dissipated to the conductive layer 12. The die 40 may be disposed on and connected to the portion 121 of the conductive layer 12. In some embodiments, the die 40 may be an IGBT. The collector of the die 40 may be connected to the portion 121. The gate and emitter of the die 40 may face away from the portion 12 of the conductive layer 12.

In some embodiments, the leadframes 61 and 62 may be disposed on and connected to the portion 121 of the conductive layer 12. In some embodiments, the leadframes 61 and 62 may include electrical connectors, other conductive structures, or a combination thereof.

In some embodiments, one or more dies may be disposed on and connected to the portion 122 of the conductive layer 12. The portion 122 of the conductive layer 12 may be connected to external components through the leadframes.

FIG. 4B is a bottom view of a substrate 10 of a power module, in accordance with some embodiments of the present disclosure. FIG. 4B shows an exemplary pattern of the substrate 10 of FIG. 1. For clarity, FIG. 4B omits the encapsulant 70 and the leadframes 61 to 68. Referring to FIG. 4B, the substrate 10 includes the core layer 11 and the conductive layer 13 free from being patterned. In some embodiments, the conductive layer 13 may be round, square, rectangular, or irregular. For example, the conductive layer 13 may be rectangular.

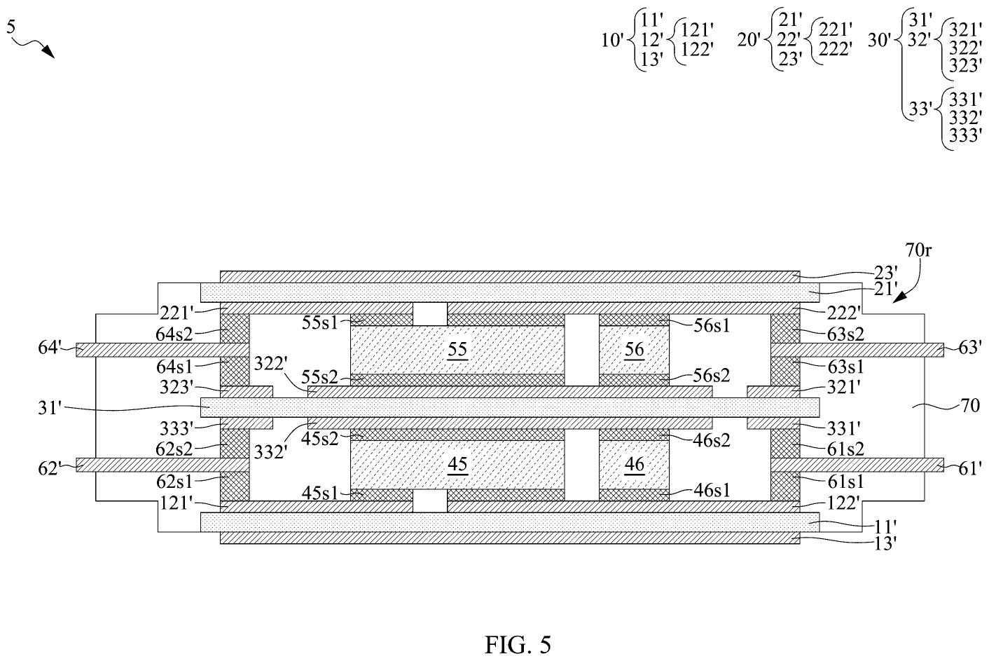

FIG. 5 is a cross-section of a power module 5, in accordance with some embodiments of the present disclosure. The power module 5 of FIG. 5 is similar to the power module 1 of FIG. 1, but with different die arrangements and fewer leadframes. In some embodiments, the power module 5 may include two dies 45 and 46 disposed between the substrates 10′ and 30′, and two dies 55 and 56 disposed between the substrates 20′ and 30′. In some embodiments, the power module 5 may include leadframes 61′ to 64′ connected to the substrate 30′. In some embodiments, the substrates 10′, 20′, 30′ in FIG. 5 may be similar to the substrates 10, 20, 30 in FIG. 1, respectively, but with different conductive pattern.

Referring to FIG. 5, the dies 45 and 46 may be disposed between the substrates 10′ and 30′. The dies 45 and 46 may be disposed between the conductive layers 12′ and 33′. In some embodiments, the dies 45 and 46 may be electrically connected to the conductive layer 12′ of the substrate 10′. The die 45 may adhere and connect to the substrate 10′ through a soldering material 45s1. The die 46 may adhere and connect to the substrate 10′ through a soldering material 46s1. In some embodiments, the dies 45 and 46 may be electrically connected to the conductive layer 33′ of the substrate 30′. The die 45 may adhere and connect to the substrate 30′ through a soldering material 45s2. The die 46 may adhere and connect to the substrate 30′ through a soldering material 46s2. In some embodiments, the soldering materials 45s1, 45s2, 46s1, and 46s2 may be solder paste, solder bumps, or solder ball, or non-solder conductive structures such as copper pillar, or a combination thereof. In some embodiments, heat generated by the dies 45 and 46 may be dissipated by the substrates 10′ and 30′. In some embodiments, a heatsink (not shown) may be disposed under the conductive layer 13′ for dissipating heat from the dies 45 and 46. That is, the substrate 10′ may be configured to establish a thermal dissipation path for the dies 45 and 46.

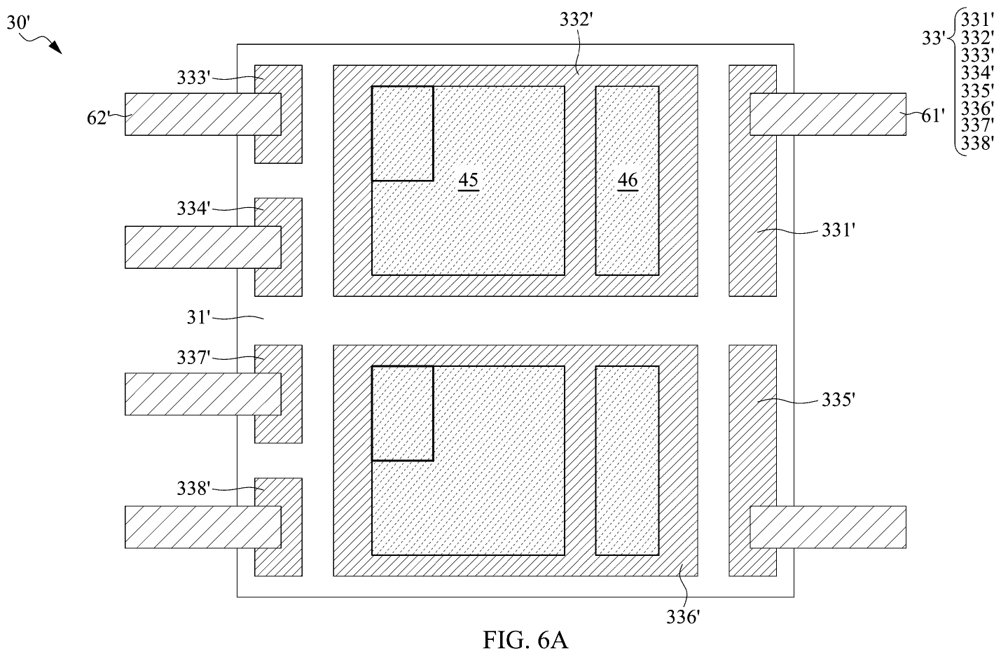

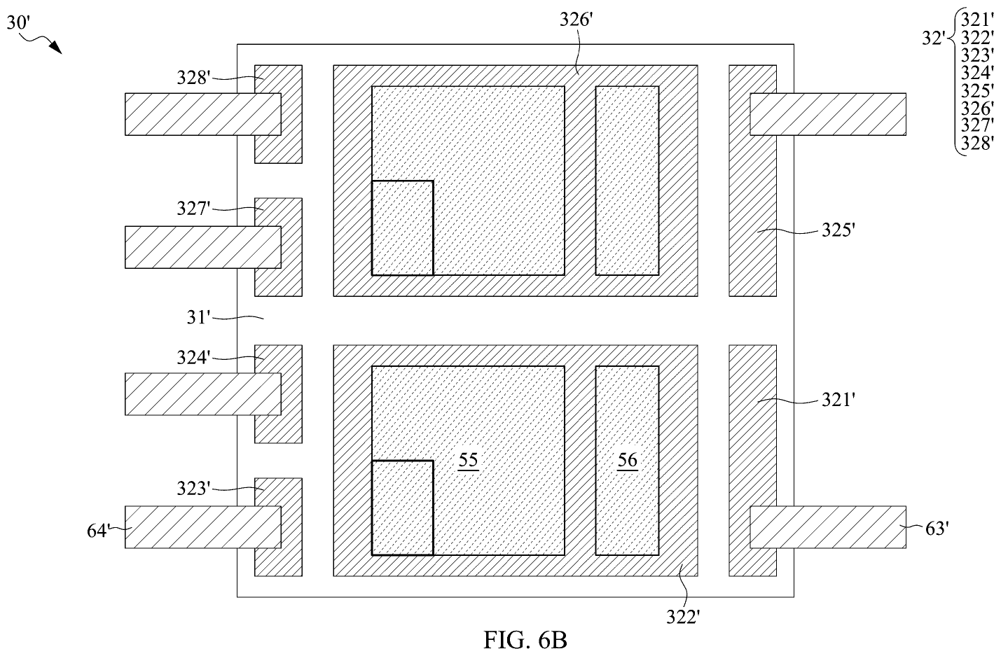

In some embodiments, a thickness of the die 45 may be substantially identical to that of the die 46. In some embodiments, die 45 may be of different size than the die 46. For example, the die 45 may be wider than the die 46. In some embodiments, an area of the die 45 may be different from that of the die 46 in a top view (see FIG. 6A). For example, the area of the die 45 may be greater than that of the die 46 in a top view (see FIG. 6A).

In some embodiments, the dies 45 and 46 may be an electronic component such as a power die. The dies 45 and 46 may be a transistor or a diode, for example an insulated gate bipolar transistor (IGBT). In some embodiments, the die 45 may be a three-terminal element, and the die 46 may be a two-terminal element. In some embodiments, the die 45 may have a first terminal connected to a portion 121′ of the conductive layer 12′, a second terminal connected to a portion 122′ of the conductive layer 12′, and a third terminal connected to the portion 332′ of the conductive layer 33′. In some embodiments, the first terminal, the second terminal, and the third terminal of the die 45 may be a gate, an emitter, and a collector of the IGBT, respectively.

In some embodiments, the dies 55 and 56 may be disposed between the substrates 20′ and 30′. The dies 55 and 56 may be disposed between the conductive layers 22′ and 32′. In some embodiments, the dies 55 and 56 may be electrically connected to the conductive layer 22′ of the substrate 20′. The die 55 may adhere and connect to the substrate 20′ through a soldering material 55s1. The die 56 may adhere and connect to the substrate 20′ through a soldering material 56s1. In some embodiments, the dies 55 and 56 may be electrically connected to the conductive layer 32′ of the substrate 30′. The die 55 may adhere and connect to the substrate 20′ through a soldering material 55s1, and to the substrate 30′ through a soldering material 55s2. The die 56 may adhere and connect to the substrate 20′ through a soldering material 56s1, and to the substrate 30′ through a soldering material 56s2. In some embodiments, the soldering materials 55s1, 55s2, 56s1, and 56s2 may be solder paste, solder bumps, or solder ball, or non-solder conductive structures such as copper pillar, or a combination thereof. In some embodiments, heat generated by the dies 55 and 56 may be dissipated by the substrates 20′ and 30′. In some embodiments, a heatsink (not shown) may be disposed above the conductive layer 23′ for dissipating heat from the dies 55 and 56. That is, the substrate 20′ may be configured to establish a thermal dissipation path for the dies 55 and 56.

In some embodiments, a thickness of the die 55 may be substantially identical to that of the die 56. In some embodiments, die 55 may be of different size than the die 56. For example, the die 55 may be wider than the die 56. In some embodiments, an area of the die 55 may be different from that of the die 56 in a top view (see FIG. 6B). For example, the area of the die 55 may be greater than that of the die 56 in a top view (see FIG. 6B).

In some embodiments, the dies 55 and 56 may be an electronic component such as a power die. The dies 55 and 56 may be a transistor or a diode, for example an insulated gate bipolar transistor (IGBT). In some embodiments, the die 55 may be a three-terminal element, and the die 56 may be a two-terminal element. In some embodiments, the die 55 may have a first terminal connected to a portion 221′ of the conductive layer 22′, a second terminal connected to a portion 222′ of the conductive layer 22′, and a third terminal connected to a portion 322′ of the conductive layer 32′. In some embodiments, the first terminal, the second terminal, and the third terminal of the die 55 may be a gate, an emitter, and a collector of the IGBT, respectively.

In some embodiments, the vertical distance between the substrate 10′ and 30′ may be different from the vertical distance between the substrate 20′ and 30′. The dies 45 and 46 may have the same thickness, and the dies 55 and 56 may have the same thickness. The thickness of the die 45 may be different from that of the die 55. In some embodiments, the thickness of the die 45 may be greater than that of the die 55. In some embodiments, the dies 45 and 55 may be the same type of power die with the different thickness, which may have different properties. Similarly, the dies 46 and 56 may be the same type of power die with the different thickness, which may have different properties.

Leadframes 61′ and 62′ may be disposed between substrates 10′ and 30′ and in some embodiments, on the substrate 10′. The leadframes 61′ and 62′ may adhere and connect to the substrate 10′ through a soldering material 61s1 and 62s1, respectively. The leadframes 61′ and 62′ may adhere and connect to the substrate 30′ through a soldering material 61s2 and 62s2, respectively. In some embodiments, the soldering material 61s1, 61s2, 62s1, and 62s2 may be solder paste, solder bumps, or solder ball, or non-solder conductive structures such as copper pillar, or a combination thereof. The leadframes 61′ and 62′ may be electrically connected the substrates 10′ and 30′. The leadframes 61′ and 62′ may connect the dies 45 and 46 to the external components or other electrical connection.

Leadframes 63′ and 64′ may be disposed between substrates 20′ and 30′. The leadframes 63′ and 64′ may adhere and connect to the substrate 30′ through a soldering material 63s1 and 64s1, respectively. The leadframes 63′ and 64′ may adhere and connect to the substrate 20′ through a soldering material 63s2 and 64s2, respectively. In some embodiments, the soldering material 63s1, 63s2, 64s1, and 64s2 may be solder paste, solder bumps, or solder ball, or non-solder conductive structures such as copper pillar, or a combination thereof. The leadframes 63′ and 64′ may be electrically connected to the substrates 20′ and 30′. The leadframes 63′ and 64′ may connect the dies 55 and 56 to the external components or other electrical connection.

FIG. 6A is a bottom view of a substrate 30′ of a power module, in accordance with some embodiments of the present disclosure. FIG. 6A shows an exemplary pattern of the substrate 30′ of FIG. 5. For clarity, FIG. 6A omits the substrate 10′ and encapsulant 70.

Referring to FIG. 6A, the substrate 30′ includes the core layer 31′ and the patterned conductive layer 33′. The patterned conductive layer 33′ may include one or more portions 331′, 332′, 333′, and 334′. The portions 331′, 332′, 333′, and 334′ of the conductive layers 33′ may be spaced apart from each other. In some embodiments, the portions 331′, 332′, 333′, and 334′ may be round, square, rectangular, or irregular. The shapes of the portions 331′, 332′, 333′, and 334′ may be identical or different.

The size of the portions 331′, 332′, 333′, and 334′ may be different. For example, the area of the portion 332′ may be greater than that of the portions 331′, 333′, and 334′. The area of the portion 331′ may be greater than that of the portion 333′. The area of the portion 333′ may be substantially identical to that of the portion 334′. In some embodiments, the portions 331′, 332′, 333′, and 334′ may be rectangular.

In some embodiments, the portion 332′ of the conductive layer 33′ may connect to one or more dies (such as the dies 45 and 46), such that heat generated by the dies is dissipated to the conductive layer 33′. The dies 45 and 46 may be disposed on and connected to the portion 332′. In some embodiments, the die 45 may be an IGBT and the die 46 may be a diode. The collector of the die 45 may be connected to the portion 332′. The gate and emitter of the die 45 may face away from the conductive layer 33′.

In some embodiments, the leadframe 61′ may be disposed on and connected to the portion 331′ of the conductive layer 33′. In some embodiments, the leadframe 62′ may be disposed on and connected to the portion 333′ of the conductive layer 33′. In some embodiments, the leadframes 61′ and 62′ may include electrical connectors, other conductive structures, or a combination thereof. In some embodiments, another leadframe may be disposed on and connected to the portion 334′ of the conductive layer 33′.

FIG. 6B is a top view of a substrate 30′ of a power module, in accordance with some embodiments of the present disclosure. FIG. 6B shows an exemplary pattern of the substrate 30′ of FIG. 5. For clarity, FIG. 6B omits the substrate 20′ and encapsulant 70.

Referring to FIG. 6B, the substrate 30′ includes the core layer 31′ and the patterned conductive layer 32′. The patterned conductive layer 32 may include one or more portions 321′, 322′, 323′, and 324′. The portions 321′, 322′, 323′, and 324′ of the conductive layers 32 may be spaced apart from each other. In some embodiments, the portions 321′, 322′, 323′, and 324′ may be round, square, rectangular, or irregular. The shapes of the portions 321′, 322′, 323′, and 324′ may be identical or different.

The size of the portions 321′, 322′, 323′, and 324′ may be different. For example, the area of the portion 322′ may be greater than that of the portions 321′, 323′, and 324′. The area of the portion 321′ may be greater than that of the portion 323′. The area of the portion 323′ may be substantially identical to that of the portion 324′. In some embodiments, the portions 321′, 322′, 323′, and 324′ may be rectangular.

In some embodiments, the portion 322′ of the conductive layer 32′ may connect to one or more dies (such as the dies 55 and 56), such that heat generated by the dies is dissipated to the conductive layer 32′. The dies 55 and 56 may be disposed on and connected to the portion 322′. In some embodiments, the die 55 may be an IGBT and the die 56 may be a diode. The collector of the die 55 may be connected to the portion 322′. The gate and emitter of the die 46 may face away from the conductive layer 32′.

In some embodiments, the leadframe 63′ may be disposed on and connected to the portion 321′ of the conductive layer 32′. In some embodiments, the leadframe 64′ may be disposed on and connected to the portion 323′ of the conductive layer 32′. In some embodiments, the leadframes 63′ and 64′ may include electrical connectors, other conductive structures, or a combination thereof. In some embodiments, another leadframe may be disposed on and connected to the portion 324′ of the conductive layer 32′.

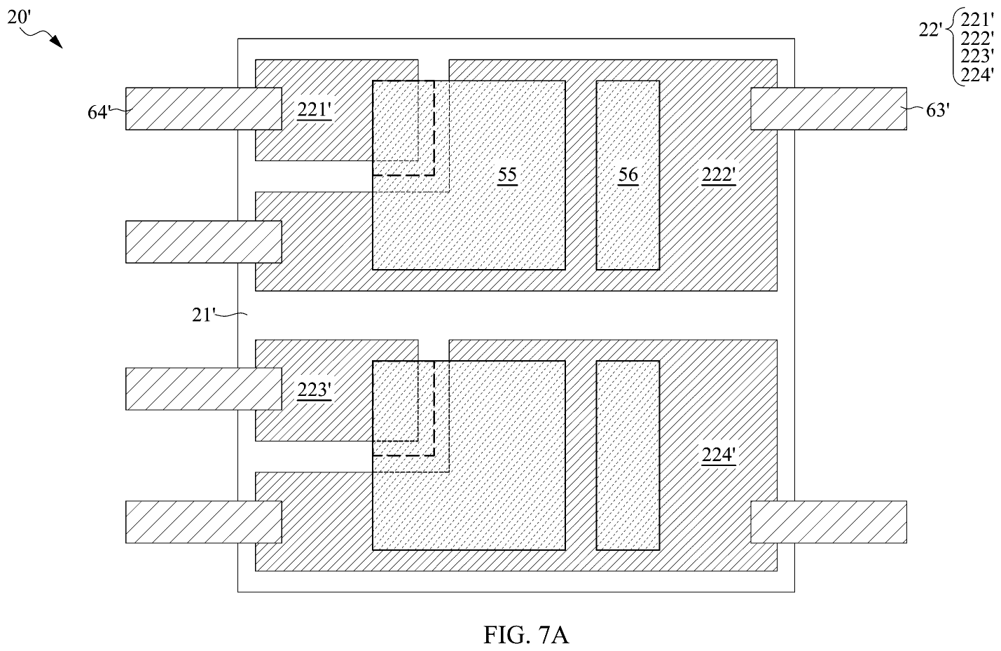

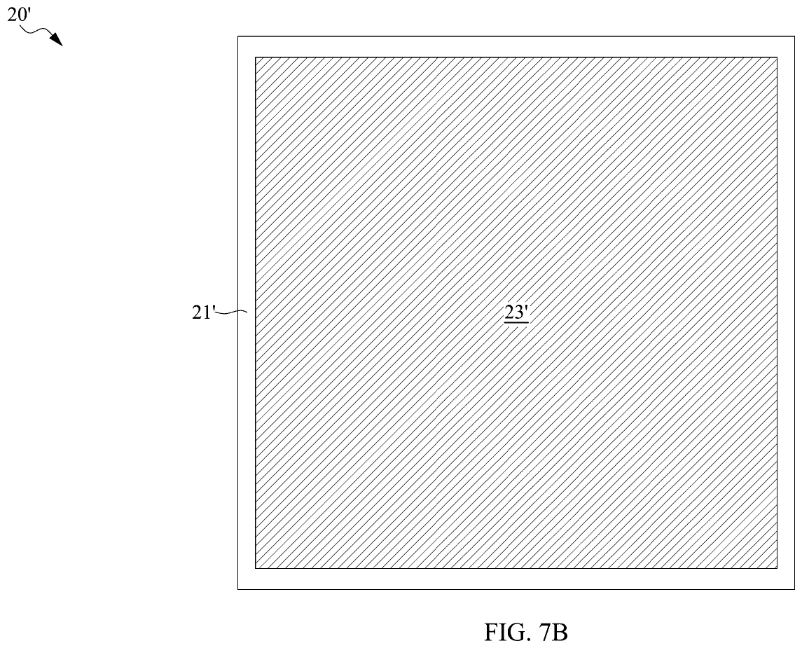

FIG. 7A is a bottom view of a substrate 20′ of a power module, in accordance with some embodiments of the present disclosure. FIG. 7A shows an exemplary pattern of the substrate 20′ of FIG. 5. For clarity, FIG. 7A omits the encapsulant 70, the substrates 10′ and 30′, and the leadframes 61′ and 62′.

Referring to FIG. 7A, the substrate 20′ includes the core layer 21′ and the patterned conductive layer 22′. The patterned conductive layer 22′ may include one or more portions 221′ and 222′. The portions 221′ and 222′ of the conductive layer 22′ may be spaced apart from each other. In some embodiments, the portions 221′ and 222′ may be round, square, rectangular, or irregular. The shapes of the portions 221′ and 222′ may be identical or different.

The size of the portions 221′ and 222′ may be different. For example, the area of the portion 222′ may be greater than that of the portion 221′. In some embodiments, the portion 221′ may be rectangular and the portion 222′ may be L-shape.

In some embodiments, the portions 221′ and 222′ of the conductive layer 22′ may connect to one or more dies (such as the dies 55 and 56), such that heat generated by the dies is dissipated to the conductive layer 22′. The die 55 may be disposed on the portions 221′ and 222′. In some embodiments, the die 55 may be connected to the portions 221′ and 222′ through two terminals, respectively. For example, the portion 221′ may be connected to a first terminal of the die 55 (for example, the gate), and the portion 222′ may be connected to a second terminal of the die 55 (for example, the emitter). The collector of the die 55 may face away from the conductive layer 22′. In some embodiments, the die 56 may be disposed on and connected to the portion 222′.

In some embodiments, the leadframes (such as the leadframes 63′ and 64′) may be connected to the conductive layer 22′, such that the dies 55 and 56 may be connected to external components through the leadframes.

FIG. 7B is a top view of a substrate 20′ of a power module, in accordance with some embodiments of the present disclosure. FIG. 7B shows an exemplary pattern of the substrate 20′ of FIG. 5. For clarity, FIG. 7B omits the encapsulant 70 and the leadframes 61′ to 64′. Referring to FIG. 7B, the substrate 20′ includes the core layer 21′ and the conductive layer 23′ free from being patterned. In some embodiments, the conductive layer 23′ may be round, square, rectangular, or irregular. For example, the conductive layer 23′ may be rectangular.

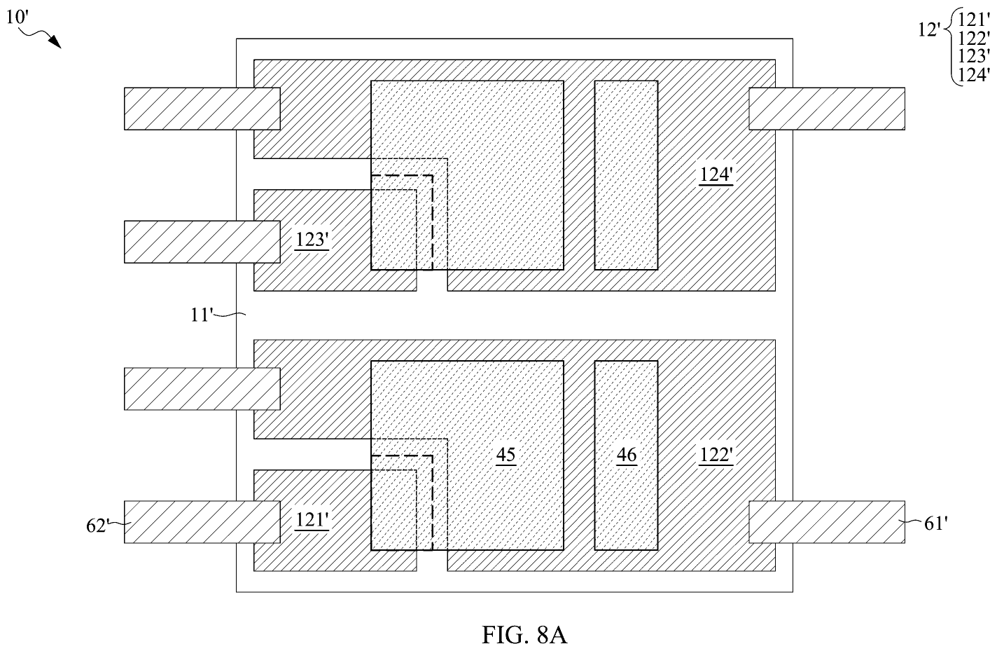

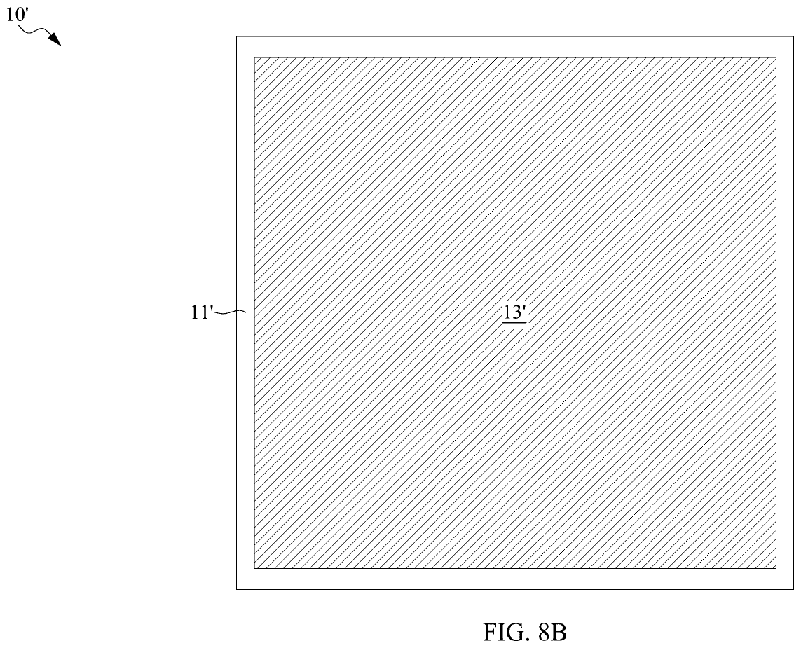

FIG. 8A is a top view of a substrate 10′ of a power module, in accordance with some embodiments of the present disclosure. FIG. 8A shows an exemplary pattern of the substrate 10′ of FIG. 5. For clarity, FIG. 8A omits the encapsulant 70, the substrates 20′ and 30′, and the leadframes 63′ and 64′.

Referring to FIG. 8A, the substrate 10′ includes the core layer 11′ and the patterned conductive layer 12′. The patterned conductive layer 12′ may include one or more portions 121′ and 122′. The portions 121′ and 122′ of the conductive layer 12′ may be spaced apart from each other. In some embodiments, the portions 121′ and 122′ may be round, square, rectangular, or irregular. The shapes of the portions 121′ and 122′ may be identical or different.

The size of the portions 121′ and 122′ may be different. For example, the area of the portion 122′ may be greater than that of the portion 121′. In some embodiments, the portion 121′ may be rectangular and the portion 122′ may be L-shape.

In some embodiments, the portions 121′ and 122′ of the conductive layer 12′ may connect to one or more dies (such as the dies 45 and 46), such that heat generated by the dies is dissipated to the conductive layer 12′. The die 45 may be disposed on the portions 121′ and 122′. In some embodiments, the die 45 may be connected to the portions 121′ and 122′ through two terminals, respectively. For example, the portion 121′ may be connected to a first terminal of the die 45 (for example, the gate), and the portion 122′ may be connected to a second terminal of the die 45 (for example, the emitter). The collector of the die 45 may face away from the conductive layer 12′. In some embodiments, the die 46 may be disposed on and connected to the portion 122′.

In some embodiments, the leadframes (such as the leadframs 61′ and 62′) may be connected to the conductive layer 22′, such that the dies 45 and 46 may be connected to external components through the leadframes.

FIG. 8B is a bottom view of a substrate 10′ of a power module, in accordance with some embodiments of the present disclosure. FIG. 8B shows an exemplary pattern of the substrate 10′ of FIG. 5. For clarity, FIG. 8B omits the encapsulant 70 and the leadframes 61′ to 64′. Referring to FIG. 8B, the substrate 10′ includes the core layer 11′ and the conductive layer 13′ free from being patterned. In some embodiments, the conductive layer 13′ may be round, square, rectangular, or irregular. For example, the conductive layer 13′ may be rectangular.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A power module, comprising:
a first substrate having a first surface and a second surface opposite to the first surface;
a first die disposed on the first surface of the first substrate; and
a second die disposed on the second surface of the first substrate, wherein at least one of the first die and the second die is a power die,
wherein a first thickness of the first die is different from a second thickness of the second die.

2. The power module of claim 1, wherein the first substrate comprises:
a core layer having a first surface and a second surface opposite to the first surface;
a first conductive layer disposed on the first surface of the core layer; and
a second conductive layer disposed on the second surface of the core layer.

3. The power module of claim 1, further comprising a second substrate disposed on the first surface of the first substrate, wherein the second substrate comprises:
a first conductive layer connected to the first die and being patterned;
a second conductive layer disposed under the first conductive layer and free from being patterned; and
a core layer disposed between the first conductive layer and the second conductive layer.

4. The power module of claim 3, further comprising an encapsulant encapsulating the first core layer and the first conductive layer, wherein the second conductive layer is exposed by the encapsulant.

5. The power module of claim 4, wherein the second conductive layer is free from contacting the encapsulant.

6. The power module of claim 1, wherein the second die vertically overlaps the first die in a cross-sectional view.

7. The power module of claim 1, wherein a projection of the second die on the first substrate is completely within a projection of the first die on the first substrate.

8. A power module, comprising:
a first substrate having a first surface and a second surface opposite to the first surface;
a first power die disposed on the first surface of the first substrate; and
a second power die disposed on the second surface of the first substrate, wherein a first area of the first power die is different from a second area of the second power die from a top view.

9. The power module of claim 8, further comprising a third power die disposed on the first surface of the first substrate, wherein a width of the first power die is greater than a respective width of each of the second power die and the third power die in a cross sectional view.

10. The power module of claim 9, further comprising a second substrate disposed on the second surface of the first substrate, wherein the second substrate is spaced apart from the first substrate by a uniform distance, and wherein the second power die and the third power die are disposed between the first substrate and the second substrate.

11. The power module of claim 10, wherein a thickness of the second power die is substantially identical to a thickness of the third power die.

12. The power module of claim 11, wherein the second power die is connected to the first substrate through a first soldering material, and the third power die is connected to the first substrate through a second soldering material, wherein a thickness of the first soldering material is different from a thickness of the second soldering material.

13. The power module of claim 8, wherein the first substrate includes a first conductive layer including a first portion and a second portion spaced apart from the first portion, wherein the first portion is connected to the second power die, and the second portion is connected to the third power die.

14. The power module of claim 8, further comprising a second substrate disposed on the first surface of the first substrate, wherein the second substrate comprises:
a core layer having a first surface and a second surface opposite to the first surface;
a first conductive layer disposed on the first surface of the core layer and being patterned; and
a second conductive layer disposed on the second surface of the core layer and free from being patterned.

15. The power module of claim 14, wherein the first conductive layer of the second substrate includes a first portion and a second portion spaced apart from the first portion, wherein the first portion is connected to the second power die and the third power die.

16. The power module of claim 14, further comprising an encapsulant covering a lateral surface of the core layer.

17. A power module, comprising:
a first substrate having a first surface and a second surface opposite to the first surface;
a first die disposed on the first surface of the first substrate; and
a second die disposed on the second surface of the first substrate,
wherein at least one of the first die and the second die is a power die, and wherein the first die and the second die are misaligned in a cross sectional view.

18. The power module of claim 17, wherein a first lateral surface of the second die is misaligned with a first lateral surface of the first die.

19. The power module of claim 18, wherein the second die has a second lateral surface opposite to the first lateral surface, wherein a projection of the second lateral surface of the second die on the first substrate is within a projection of the first die on the first substrate.

20. The power module of claim 18, wherein a projection of the first lateral surface of the second die on the first substrate is outside a projection of the first die on the first substrate.
